(19) United States
(12) Patent Application Publication
(10) Pub. No.: US 2023/0240022 A1
(43) Pub. Date: Jul. 27, 2023

(54) HYBRID PROCESS FOR PCB PRODUCTION BY LAD SYSTEM

(71) Applicant: IO Tech Group Ltd., London (GB)

(72) Inventors: Ralph S. Birnbaum, Nes Ziona (IL); Guy Nesher, Nes Ziona (IL); Alexander Slavomir Stepinski, Saunderstown, RI (US); Michael Zenou, Hashmonaim (IL)

(21) Appl. No.: 17/649,100

(22) Filed: Jan. 27, 2022

(51) Int. Cl. H05K 3/46; C23C 14/28; B23K 26/342

(52) U.S. Cl. CPC H05K 3/4664; C23C 14/28; B23K 26/342; H05K 3/4682; H05K 2203/107; H05K 2203/1131; H05K 2203/1492; B23K 2101/42

(57) ABSTRACT

Systems and methods for printing a printed circuit board (PCB) from substrate to full integration utilize a laser-assisted deposition (LAD) system to print a flowable material on top of a substrate by laser jetting to create a PCB structure to be used as an electronic device. One such system for PCB printing includes a jet printing unit, an imaging unit, curing units, and a drilling unit to print metals and other materials (e.g., epoxies, solder masks, etc.) directly on a PCB substrate such as a glass-reinforced epoxy laminate material (e.g., FR4). The jet printing unit can also be used for sintering and/or ablating materials. Printed materials are cured by heat or by infrared (IR) or ultraviolet (UV) radiation. PCBs produced according to the present systems and methods may be single-sided or double-sided.

### FIELD OF THE INVENTION

The present invention relates to systems and methods for manufacturing a printed circuit board (PCB) or a flexible PCB, and more specifically relates to printing one or more components of the PCB.

### BACKGROUND

Surface mount technology (SMT) is an area of electronic assembly used to mount electronic components to the surface of a PCB as opposed to inserting components through holes in the PCB as in conventional assembly. SMT was developed to reduce manufacturing costs and allow efficient use of PCB space. As a result of the introduction of SMT and ever-increasing levels of automation, it is now possible to build highly complex electronic circuits into smaller and smaller assemblies with good repeatability.

The recent trend toward miniaturization has created a need for the fabrication of highly integrated PCBs. PCBs are generally fabricated by lithography using extractive methods, for example by etching. Such a fabrication method typically forms conductive lines by placing a conductive film on a substrate and etching away unnecessary portions of the conductive film with a corrosive solution in order to form the conductive lines. In addition, to improve integration, multi-layered PCBs and double-sided PCBs are required. Current fabrication of multi-layered printed circuit boards requires complicated processes including drilling to form through holes in order to enable conduction between multilayer boards, laminating the boards and soldering to adhere elements to the printed circuit board. When soldering is performed to adhere elements to the printed circuit board, an area larger than the size of elements themselves is required for each of the elements to accommodate the soldering, which limits miniaturization. Therefore, there is a need for devices and methods enabling efficient and precise fabrication of complex circuit boards.

Flexible-rigid composite electronics represent a new generation of electronics, which can exhibit properties of both stretching as well as bending flexibility. These properties will afford electronic devices with conformity to bending and twisting as well as the capability to stretch and compress over a large strain scale. Because of their soft and conformable nature, stretchable electronics have shown great potential in biomedical engineering (e.g., in epidermal electronic devices and implantable devices), as well as in the growing demand for wearable electronics, and other industries such as sensors, antennas with complex geometry, or radio frequency identification (RFID) tags to be placed on curved objects.

Progress in the field of flexible electronics is expected to play a critical role in a number of important emerging technologies. For example, flexible sensor arrays, electronic paper, wearable electronic devices, and large area flexible active matrix displays. In addition, development of flexible integrated electronic systems and processing methods is also expected to significantly impact several other important technologies including micro- and nano-fluidics, sensors and smart skins, RFID, information storage, and micro- and nanoelectromechanical systems.

Flexible electronics currently refers to a technology for building electronic circuits by depositing electronic devices onto flexible substrates. Fabricating flexible electronics with performance that is equal to conventional (rigid) microelectronics built on brittle semiconductor wafers, and at the same time being optically transparent, light-weight, stretchable/bendable formats, and easy to print rapidly over large areas has been shown to enable diverse applications, such as flexible displays, thin film solar cells, and large area sensors and actuators. In all of these applications, the flexibility of both the circuits and the components incorporated on them represents important differences from typically rigid circuits. To date, it has proven to be a challenge to design a bendable (governed by Young's modulus, a modulus of elasticity describing a material property or parameter which is equal to a ratio between a mechanical tension and a corresponding elongation and thus a measure of the stiffness of a material) and stretchable (governed by Poisson's ratio, referring to the measurement of the relative change in width with a change in length, or the tendency of the component to “neck in” during stretching) electronics based on inorganic materials due to their small fracture strain (high Young's modulus and Poisson ratio of 1). Typical embodiments of flexible electronics include thin film inorganics adopted as semiconductors, conductors, and/or insulators on substrates to minimize strains induced by bending or stretching. Another embodiment is represented by circuits in wavy patterns, which can offer fully reversible stretchability/compressibility without substantial strains in the circuit materials themselves.

In conventional PCB fabrication, vias are provided for vertically connecting copper layers of the PCB. Vias are formed when holes drilled through a laminated board are copper plated forming a conductive barrel through the drilled hole. The barrel makes electrical contact to copper pads etched on the various layers and assures connection between them. Mechanically drilled, the holes extend through the entire thickness of the board, and there are practical limits to how small the drill diameter may be.

The object of high-density interconnect (HDI) is to achieve higher wiring density than conventional boards, and a central feature of the technology is the micro-via, (i.e., blind vias defined by hole diameters smaller than 150 μm and normally drilled by laser). The micro-via only extends between two, or at most three layers, and is usually used in combination with buried vias and regular conventional vias. A prime example of HDI technology is the ball grid array (BGA) package itself which is a printed circuit board with extremely small features.

### SUMMARY OF THE INVENTION

The present inventors have recognized that it is desirable to have a “one stop shop” to produce PCBs with a particular focus on HDIs or other similar technologies, replacing a very slow and highly complex technology that presently utilizes approximately twenty stages to produce a single PC board even before the placement of the outer layers of the PCB.

Accordingly, the present invention relates to systems and methods for printing a PCB, whether rigid or flexible. Various embodiments of the invention utilize a laser-assisted deposition (LAD) system to print a flowable material on top of a substrate by laser jetting to create a PCB structure to be used as an electronic device in a production line. In one embodiment, a system for PCB printing includes a jet printing unit, an imaging unit, curing units, and a drilling unit that print directly on a board substrate such as a copper clad laminate with a top copper layer or other layers. The jet printing unit can also be used for sintering and/or ablating materials. Such a system can print copper or other metal pastes, epoxies or other dielectric materials, and cure them by heat or by ultraviolet (UV) radiation. Such a system can also print epoxy in joints of copper lines, e.g., where the epoxy layer is printed as a bridge on top of a copper line on the substrate to create a final structure such as HDI. PCBs produced according to the present systems and methods may be one-sided or double-sided.

In some embodiments of the present invention, a PCB board is produced using LAD at a high speed.

In some embodiments of the present invention, the substrate can be a copper film with a thickness in the range from 17-100 microns, as commonly used today in the industry. However, newer technologies are already being developed to reduce this film thickness and there are industrial processes that can create a film as thin as 3 microns on top of a substrate that is used as a release or liner that will be removed at the end of the process. It is important to realize that that technology is evolving, and thinner films or different liners can be used for the process, but the current invention can still be utilized regardless of changes in one or both of the material of the liner and the thickness of the film.

In some embodiments of the present invention, a metal layer and dielectric layer are printed on top of the substrate. The metal layer (or also called the metal trace) is printed from a metal paste of any metal, but generally a copper paste will be selected as the metal paste. After the printing step, the metal paste may be dried to evaporate the solvent within the metal paste and subsequently, the metal trace can be sintered by a laser to increase the conductivity of the metal trace. To increase the resolution, each side of the metal trace can also be ablated, making it possible to decrease the width of the metal trace, and fabricate a much denser layer of metal traces, which is increasingly being demanded by the electronics industry.

In some embodiments of the present invention, properties of the dielectric layer include:
a. Mechanical properties—the dielectric layer provides the PCB assembly its strength and flexibility. During production, the PCB assembly undergoes a series of heating cycles and during those cycles, the dimensions of the PCB should remain unchanged. For that end, the board glass temperature (Tg) should be very high in the range of 250° C. and preferably should be above such temperature.
b. Coefficient of thermal expansion (CTE)—the dielectric material is positioned in the same layer as the metal traces and during the above mentioned heating cycles, both the metal trace and the dielectric material will expand. However, if the CTE of both materials is not similar enough, cracks will develop in the interfaces between the two materials during the heating cycles. Therefore, the dielectric material CTE should be very low, lower than 40° C.⁻¹ and preferably lower than 25° C.⁻¹.
c. Dielectric constant and dielectric loss—the dielectric material is used as a dielectric barrier between the metal traces to avoid interference between the electronic conduction in the different lines. For that end, both the dielectric constant and its loss need to be tailored for the application. Typical values of the dielectric constant that are used are 2.8-3 and the loss should be lower than 0.01. However, there is a continuous demand to reduce both of these numbers.
d. Adhesion—the dielectric material is used for connecting the different layers (metal or dielectric layers) and the adhesion between the layers during the heating cycles is a very important parameter. A good adhesion between the layers will decrease the rate of delamination and increase the production yield.

In some embodiments of the present invention, the dielectric material that is used in the LAD system preferably has all the above-noted properties and some industrial materials are known to have those properties. For example, KERIMID® polyimide resin, distributed by Huntsman Corporation of The Woodlands, Tex., is one possible dielectric material for the LAD system that would possess the above-described properties. The main advantage provided by the LAD system for printing the dielectric material is its ability to print high viscosity materials that have a high percentage of large particles. That property of the LAD system enables one to design a material according to the above demands rather easily as compared to any other system in the market.

In some embodiments of the present invention, the dielectric material that will be used by the system can be a UV-cured or heat-cured material.

In some embodiments of the present invention, through the printing of many layers one on top of another, the final structure of the PCB substrate will be produced, including vias and traces.

In some embodiments of the present invention, after all the layers of the PCB substrate are deposited, an additional substrate is added on top of the PCB substrate. The PCB substrate sandwiched between two substrates is pressed by a hot press at a predefined temperature for a predefined time in a predefined heating cycle while the two outer substrates are used for protecting the PCB substrate. If liners are used in the process, they can be removed after the hot press process.

In some embodiments of the present invention, after the PCB substrate has been produced, other processes that are known in the industry and are used commonly can be performed on the PCB substrate. As such, these other processes will only be described at a high level of detail, for the sake of conciseness. The phrase “hybrid process” is used to describe an overall process which involves a LAD printing process to form a PCB substrate (using the LAD system described herein), followed by conventional post processing of the PCB substrate (using conventional apparatus not depicted or described herein).

In one embodiment, the present invention provides a method of fabricating of a PCB assembly in which a metal layer is deposited on the PCB substrate by LAD, in which metal droplets from a donor substrate are jetted onto the PCB substrate and/or into one or more through holes therein using a laser to form a layer of metal on the PCB substrate. The metal layer is subsequently dried and sintered, and the jetting, drying, and sintering are repeated until the metal layer reaches a desired thickness. Thereafter, at least one passivation layer is formed over the metal layer. If needed, the metal layer may be ablated (e.g., using the same laser as was used for the deposition) if it exceeds the desired thickness. The passivation layer may be a layer of dielectric material that is deposited or coated over the metal layer using a roller or blade. Alternatively, the passivation layer may be a layer of dielectric material printed, by LAD, over the metal layer from a donor substrate coated with a dielectric material. If needed, one or more additional metal layers and dielectric layers may be similarly printed using LAD. The dielectric layer may be cured by hot air and/or infrared (IR) irradiation.

In some instances, the metal layer may include a first metal trace, and the dielectric layer may include at least a first portion of epoxy or other dielectric material that covers at least a first portion of the first metal trace. Additional metal layers printed over the dielectric layer may thus include a second metal trace having at least a portion disposed over the first portion of the dielectric layer that covers the first portion of the first metal trace. That is, the dielectric layer may form a bridge over which the second metal trace can cross the first metal trace of the PCB substrate without causing a short circuit.

In further embodiments, the present invention provides a method of fabricating of a PCB assembly that includes printing, by LAD, a metal onto a dielectric laminate. The metal may be jetted as droplets from a metal coating or foil on a donor substrate by a laser into channels and/or through holes created in the dielectric laminate by laser engraving. Subsequently, the dielectric laminate may be attached, by hot pressing, to a PCB substrate or a previously formed dielectric layer disposed over a PCB substrate. The metal jetted into the channels and/or through holes of the dielectric laminate may be sandwiched between the PCB substrate and the dielectric laminate.

In yet additional embodiments, the present invention provides a system for fabricating a PCB assembly in which a substrate holder, configured to hold a PCB substrate, is translatable between a plurality of processing stations, including a printing station configured for LAD of one or more materials (e.g., metal paste and dielectric, etc.) by jetting respective ones of the materials individually from respective donor substrates on which the respective ones of said materials are coated or otherwise disposed, and a curing station configured to cure by heating, IR irradiation, or UV irradiation, deposited ones of the materials on the PCB substrate, and a drilling station configured to drill or engrave through holes in the PCB substrate and/or layers of ones of the materials disposed thereon. The printing station may also be configured for laser sintering and/or laser ablation of the respective ones of the materials printed on the PCB substrate and/or additional layers of said PCB assembly. A unit configured to flip the PCB substrate to allow access to both sides of the PCB substrate by the printing station, curing station, and/or drilling station may also be provided.

In yet another embodiment, the present invention provides a method for fabricating a PCB assembly in which one or more through holes are drilled or laser engraved in a PCB substrate from a first side of the PCB substrate. The through holes do not extend through an entire thickness of the PCB substrate. A metal paste is deposited, by LAD, over at least a first portion of the PCB substrate and into one or more of the through holes to a first thickness. The depositing is performed by jetting small volumes of metal paste from a donor film on a first carrier substrate by an incident laser beam onto the PCB substrate and into the one or more through holes, curing the metal paste deposited on the PCB substrate and into the one or more through holes, sintering the deposited and cured metal paste using a same laser that was used for depositing the metal paste, and repeating the depositing, curing and sintering of the metal paste, thereby forming successive thicknesses thereof on the PCB substrate and in the one or more through holes, until a desired thickness of the metal paste on the PCB substrate and in the one or more through holes is reached. Then, a passivation layer is printed by LAD on the desired thickness of metal paste on the PCB substrate and in the one or more through holes, followed by the curing of the passivation layer. The LAD printing may include jetting small volumes of dielectric material from a second carrier substrate using the same laser that was used for depositing the metal paste.

In various instances, the PCB substrate is moved between the drilling, the depositing, the printing, and the forming processes on a stage that is translatable between positions at which the drilling, the depositing, the printing, and the forming processes take place. Also, the processes of depositing the metal paste and printing the passivation layer may be performed multiple times to produce a PCB assembly having multiple layers of both metal paste and dielectric (e.g., on one or both sides of the PCB substrate). Metal electrical connectors for an electronic component may be formed within the passivation layer and/or the solder mask and the metal electrical connectors may be formed from different metals (e.g., Cu, Au, Ag, etc.).

These and further embodiments of the invention are described in greater detail below.

### BRIEF DESCRIPTION OF THE DRAWINGS

The present invention is illustrated by way of example, and not limitation, in the figures of the accompanying drawings, in which:

FIGS. 1a-1l illustrate, in a conceptual manner, different processes for fabricating a PCB substrate for any PC board assembly, in accordance with embodiments of the present invention.

FIGS. 2a-2c illustrate schematically a process of printing a metal layer onto a PCB substrate, in accordance with embodiments of the present invention.

FIGS. 3a and 3b illustrate a flow chart of the metal printing process and one variation thereof, in accordance with embodiments of the present invention.

FIGS. 4a and 4b illustrate various ways to print an epoxy layer onto the surface of a PCB substrate, by a roller or blade (FIG. 4a) or by direct printing (FIG. 4b), in accordance with embodiments of the present invention.

FIG. 4c illustrates the heating of a PCB assembly produced according to the methods illustrated in FIGS. 4a and 4b to achieve the final laminate properties, in accordance with embodiments of the present invention.

FIGS. 5a-5c illustrate additional methods to create a PCB assembly by engraving solid laminate (FIG. 5a), printing a metal layer onto the laminate (FIG. 5b), and drying and pressing against the former layers (FIG. 5c).

FIGS. 6a and 6b illustrate aspects of a system for full production of PCB assemblies, in accordance with embodiments of the present invention.

FIGS. 7a and 7b illustrate aspects of how the methods and systems of the present invention can eliminate the need for a double-sided PCB by using dielectric bridges on a single side of a PCB, thereby reducing PCB processing time.

### DETAILED DESCRIPTION OF THE INVENTION

PCB production is a highly developed field with a significant number of stages. The object of the present invention is to simplify the production process through the provision and use of a single system with several sub-modules that can construct a PCB assembly from the prepreg (i.e., a type of base material, fiberglass or fabric, that has been pre-impregnated or reinforced with resin, typically epoxy, or polyimide that is partially cured) and laminate (e.g., copper clad laminate (CCL), which is a common PCB material, and copper on one or both sides) up to a base board. Systems and methods configured in accordance with the present invention need not necessarily employ materials that are different from those used today for conventional PCB production (although such new materials may be used), but may instead use those same materials in new and different ways. Hence, in various embodiments, the present invention relates to systems and methods for printing PCB or a flexible PCB, from substrate level to full integration. As described below, embodiments of the invention may utilize LAD systems to print any flowable material on top of a substrate by laser jetting to create a PCB structure to be used as an electronic device in a production line.

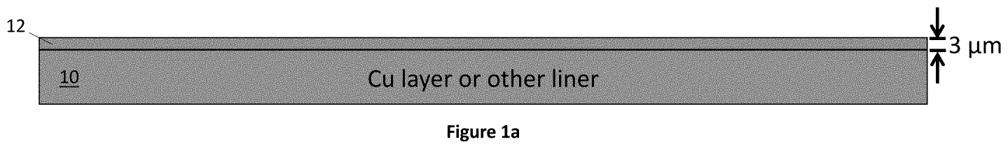

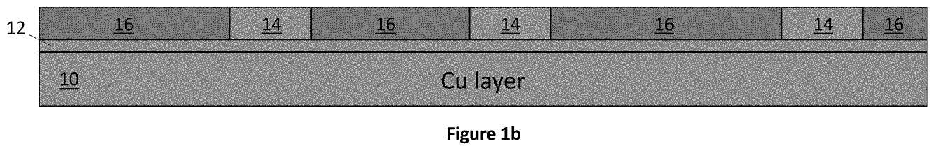

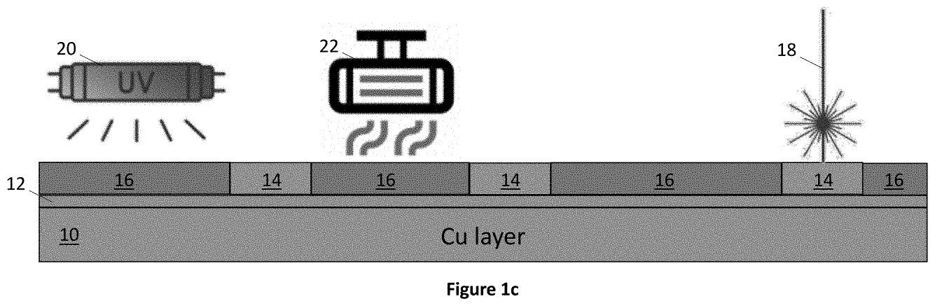

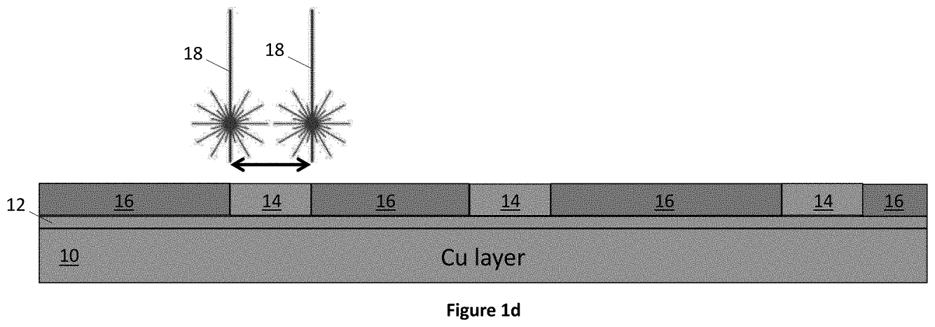

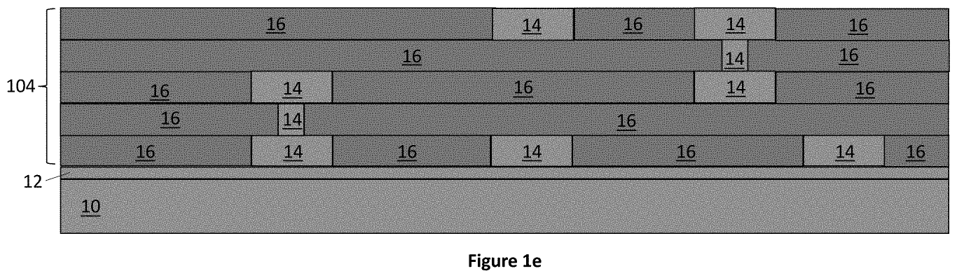

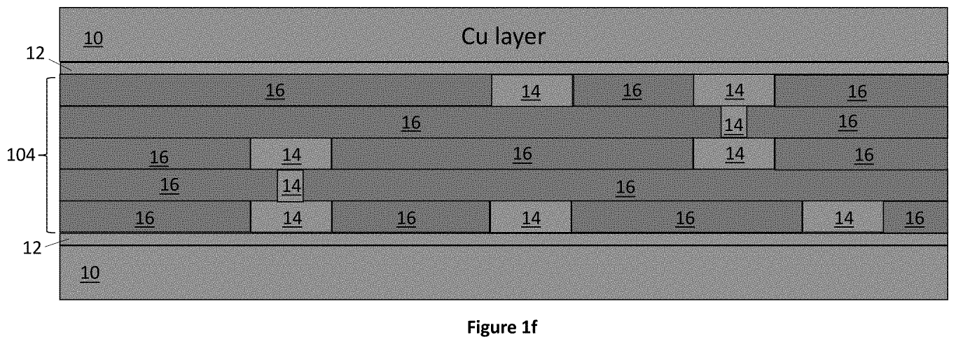

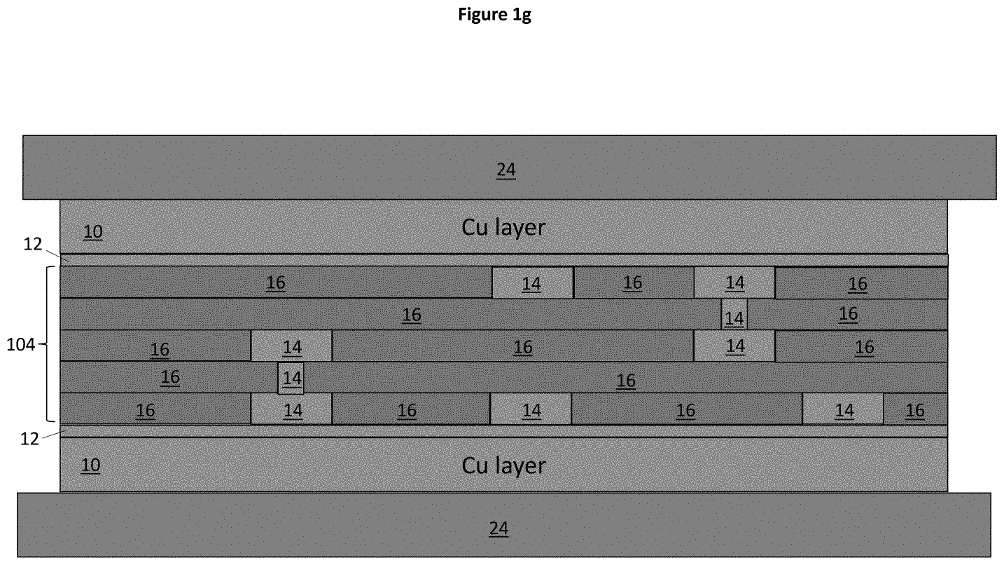

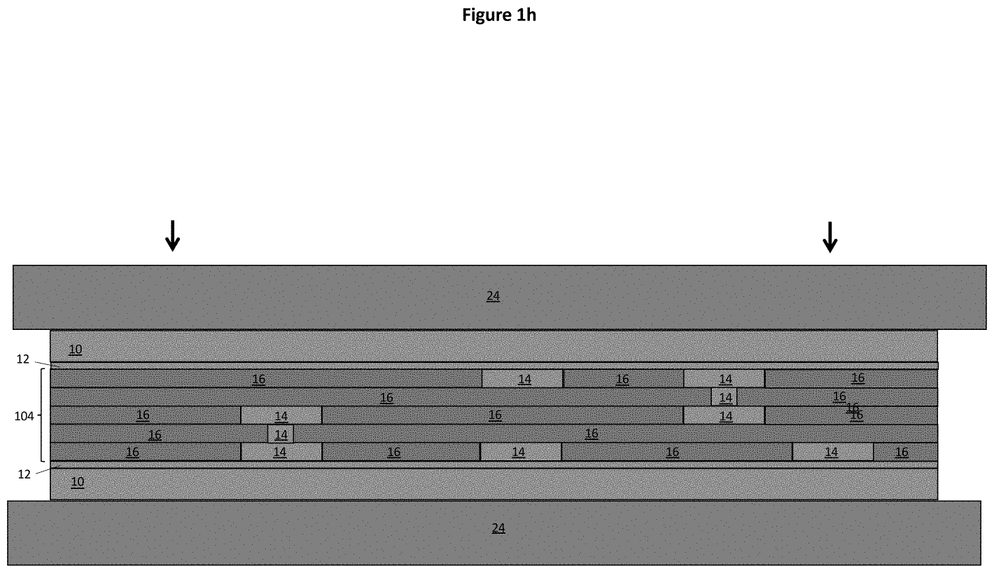

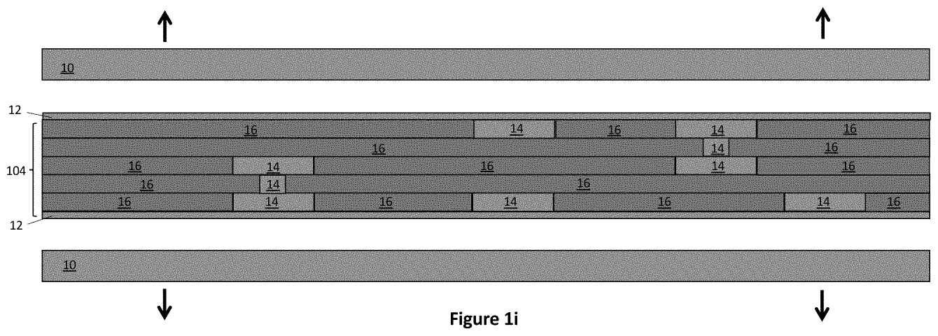

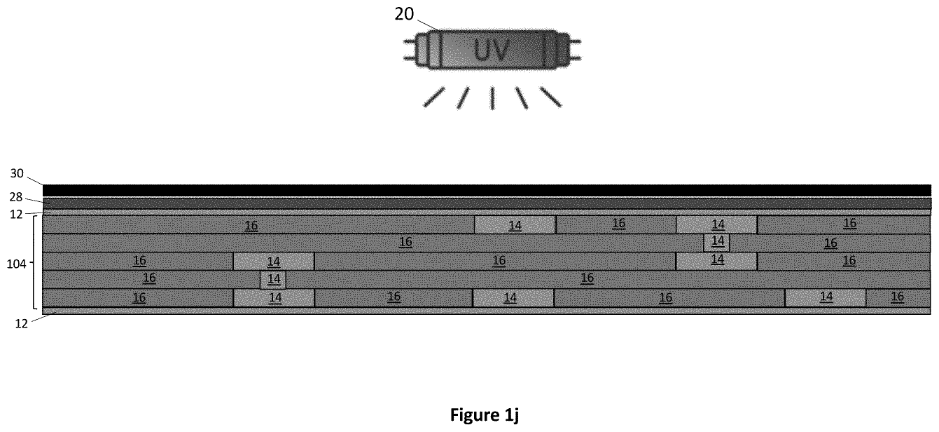

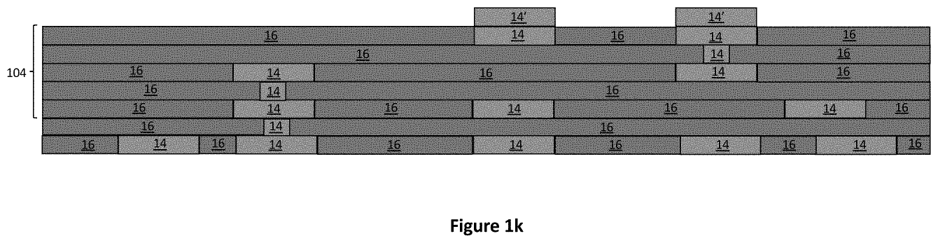

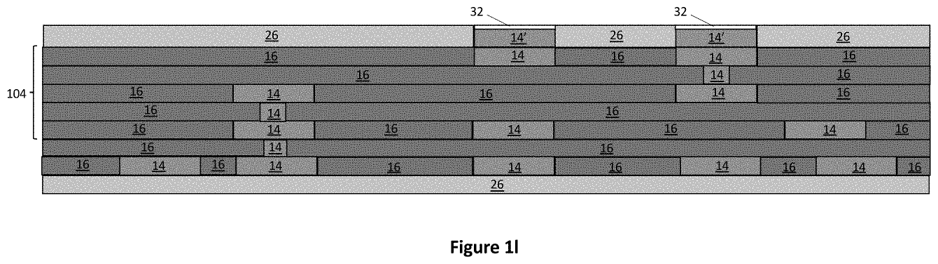

FIGS. 1a-1l illustrate the steps of a procedure to quickly produce a PCB substrate using a LAD process. FIG. 1a illustrates the basic substrate at the beginning of the process. The substrate can be a copper film with a thickness in the range from 17-100 microns, as is commonly used in the industry today. However, newer technologies are already being developed to reduce this film thickness and there are industrial processes that can create a film 12 as thin as 3 microns on top of a substrate 10 that is used as a release or liner that will be removed at the end of the process. It is important to realize that that technology is evolving, and thinner films or different liners can be used for the process, but the current invention can still be utilized regardless of changes in one or both of the material of the liner 10 or the thickness of the film 12.

As shown in the cross section depicted in FIG. 1b, the metal layer 14 and dielectric layer 16 are printed on top of the substrate 10 (or more precisely, are printed on top of the film 12). The metal layer 14 (or also called the metal trace) is printed from a metal paste of any metal, but generally a copper paste will be selected as the metal paste. After the printing step, the metal paste may be dried to evaporate the solvent within the metal paste and subsequently, the metal trace can be sintered by a laser 18 to increase the conductivity of the metal trace (FIG. 1c). To increase the resolution of the printed metal trace, each side of the metal trace can also be ablated (FIG. 1d), making it possible to decrease the width of the metal trace, and fabricate a much denser layer of metal traces, which is increasingly demanded by the electronics industry.

The dielectric layer 16 is an important part of the PCB assembly since its properties are essential for the overall quality of the PCB assembly. Properties of the dielectric layer include:
a. Mechanical properties—the dielectric layer provides the PCB assembly its strength and flexibility. During production, the PCB assembly undergoes a series of heating cycles and during those cycles, the dimensions of the PCB should remain unchanged. For that end, the board glass temperature (Tg) should be very high in the range of 250° C. and preferably should be above such temperature.
b. Coefficient of thermal expansion (CTE)—the dielectric material is positioned in the same layer as the metal traces and during the above mentioned heating cycles, both the metal trace and the dielectric material will expand. However, if the CTE of both materials is not similar enough, cracks will develop in the interfaces between the two materials during the heating cycles. Therefore, the dielectric material CTE should be very low, lower than 40° C.⁻¹ and preferably lower than 25° C.⁻¹.
c. Dielectric constant and dielectric loss—the dielectric material is used as a dielectric barrier between the metal traces to avoid interference between the electronic conduction in the different lines. For that end, both the dielectric constant and its loss need to be tailored for the application. Typical values of the dielectric constant that are used are 2.8-3 and the loss should be lower than 0.01. However, there is a continuous demand to reduce both of these numbers.
d. Adhesion—the dielectric material is used for connecting the different layers (metal or dielectric layers) and the adhesion between the layers during the heating cycles is a very important parameter. A good adhesion between the layers will decrease the rate of delamination and increase the production yield.

The dielectric material that is used in the LAD system preferably has all the above-noted properties and some industrial materials are known to have those properties. For example, KERIMID® polyimide resin, distributed by Huntsman Corporation of The Woodlands, Tex., is one possible dielectric material for the LAD system that would possess the above-described properties.

The main advantage provided by the LAD system for printing the dielectric material is its ability to print high viscosity materials that have a high percentage of large particles. That property of the LAD system enables one to design a material according to the above demands rather easily as compared to any other system in the market.

The dielectric material that will be used by the system can be a UV cured or heat cured material and for that end, a UV system 20 and a drying system 22 are provided in the LAD system to post process the dielectric material, as depicted in FIG. 1c (i.e., with post processing referring to the steps that follow the printing of a material).

FIG. 1e illustrates a cross section of the PCB substrate 104 after all the layers have been deposited, the PCB substrate 104 including vias and metal traces.

FIG. 1f illustrates a cross section of a structure, after an additional substrate 10 and film 12 have been added on top of the PCB substrate 104. The structure is then pressed by the hot press 24 at a predefined temperature for a predefined time in a predefined heating cycle while the two outer layers 10 are used for protection (FIGS. 1g-1h).

If liners 10 were in use in the process, they can be removed after the hot press process, as shown in FIG. 1i.

FIGS. 1j-1l illustrate the steps that are performed to construct a PCB assembly from the PCB substrate 104. These processes are known in the industry and are used commonly. As such, these processes will only be described at a high level of detail, for the sake of conciseness. The phrase “hybrid process” is used to describe an overall process which involves a LAD printing process to form the PCB substrate 104, followed by conventional post processing of the PCB substrate 104 (e.g., lithography to form additional metal and/or dielectric layers, and the deposition of a solder mask layer to protect metal components from oxidation) to form a PCB assembly. The conventional post processing is described below in association with FIGS. 1j-1l.

First, lithography is used to create the outer metal traces (FIGS. 1j-1k). As is known in the art, lithography generally involves depositing a layer of material (e.g., a metal), covering the layer of material with a resist layer, patterning the resist layer with UV light, removing the uncured resist, etching the exposed portions of the layer of material (e.g., a metal), then removing the cured resist. In FIG. 1j, resist layer 28 is deposited on top of film 12, which acts a seed layer for the resist. Further, mask layer 30 is deposited on top of the resist layer 28. The mask layer 30 has a plurality of openings (not shown in FIG. 1j) that allow UV light to pass through portions of the mask layer 30 in order to cure corresponding portions of the resist layer 28. The metal film 12 is processed by photolithography. In some regions, the metal film 12 acts as a seed layer for connectors and in other places, the metal film 12 is removed by a conventional photolithography process. In the regions where the metal film 12 acts as a seed layer for connectors, the metal film 12 becomes part of the metal connector 14 (and hence the metal film 12 is not depicted in FIGS. 1k and 1l).

A solder mask layer 26 is then deposited over one or both sides of the structure (leaving some metal contact regions 14′ exposed for electrical connection with electronic components) to produce the PCB assembly (FIG. 1l). The metal contact regions 14′ may also be coated with a gold coating 32 (through a gold plating process) to decrease the oxidation of the contact regions 14′, which in turn decreases the contact resistance. The current “hybrid process” decreases the time to produce the PCB substrate 104, while not altering the post processing on the PCB substrate 104 that is currently performed in the industry.

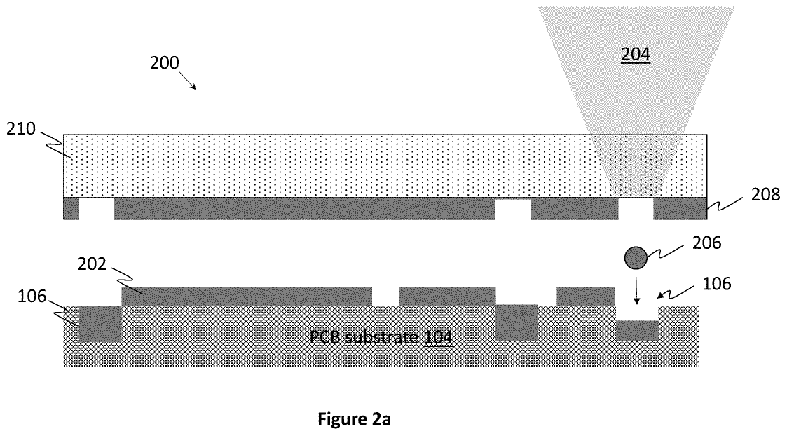

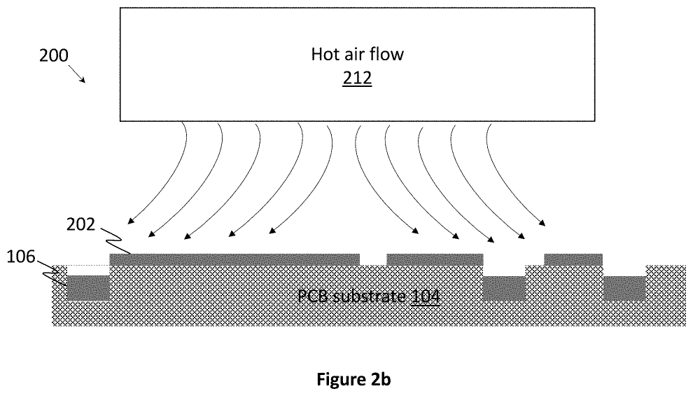

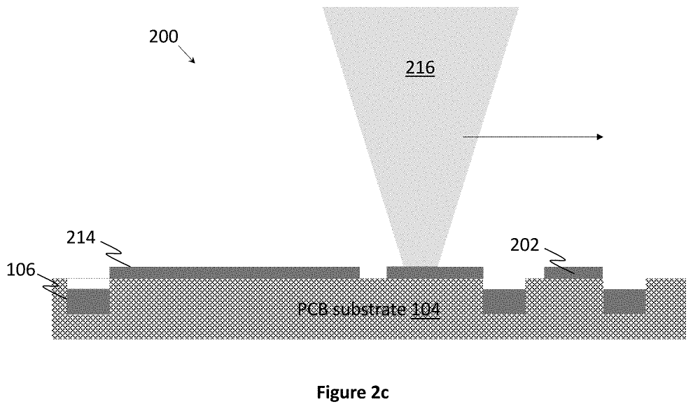

The metallization process, which is the most important part of the PCB production, may be performed by paste printing. FIG. 2a illustrates how, in a PCB board production system 200, a non-flat surface, such as a PCB substrate 104 in which through holes 106 have been engraved/drilled, is covered by a metal paste 202 by laser induced jetting. For clarity, it is noted that the layer formation processes described in FIGS. 2a-2c, 3a-3b, 4a-4c and 5a-5c describe processes to form the PCB substrate 104 depicted in FIGS. 1e-1l. Therefore, the PCB substrate 104 depicted in FIGS. 2a-2c, 4a-4c and 5c is intended to represent a partially formed version of the PCB substrate 104 depicted in FIGS. 1e-1l.

Laser induced jetting is a form of LAD in which a laser beam 204 is used to create a patterned surface by controlled material deposition. In particular, laser photons provide the driving force to catapult a small volume of metal paste 206 from a donor film 208 toward an acceptor substrate such as PCB substrate 104. Typically, the laser beam 202 interacts with an inner side of the donor film 208, which is coated onto a non-absorbing carrier substrate 210 (also called a donor substrate). In other words, the incident laser beam 204 propagates through the transparent carrier substrate 210 before the photons are absorbed by the inner surface of the film 208. Above a certain energy threshold, metal paste 206 is ejected from the donor film 208 toward the surface of the PCB substrate 104, which is situated on a stage (not shown in this view) in a work area.

Once deposited on the PCB substrate 104, including in through holes 106, the metal paste 202 is dried by hot air 212, see FIG. 2b, or by heating using an infra-red (IR) lamp or a similar arrangement and the resulting metal film 214 can be sintered using a laser beam 216 that is passed over the deposited metal paste 202 to produce a highly conductive metal (e.g., copper) film as shown in FIG. 2c. The same laser that was used for the paste deposition may be used for the sintering and can be used also for ablating deposited material that was not placed correctly—an inline repair to increase robustness.

Because the printing of the conductive film is an intermediate step, it is desirable that the formation of this layer does not take a long time. Accordingly, the metal paste from which the conductive film is formed should only take a short amount of time to cure (whether by IR irradiation, hot air, or both) and should not shrink much (if at all) during the curing process. Materials that take an excessive amount of time to cure will impede the overall speed of the process, and those that shrink (more than a negligible amount) during curing will impart mechanical stress on the PCB substrate, which may lead to failure.

The active or conductive material used for the conductive film may comprise one or more metals. Metals that are contemplated include pure metals, metal alloys, and refractory metals. Copper is a common choice for PCB metallization, and may be used in embodiments of the present invention. The active material may be applied (printed) using LAD either from a solid state, e.g., small metal particles that are deposited on a plastic film can be used in the LAD process to generate a conductive layer, or in the form of a paste carried on a donor film 208 as described above. The conductive film should be applied in an amount sufficient to fully support the subsequent electronic connections. This may mean applying several layers of paste, one atop the other, with curing steps after each application of a layer.

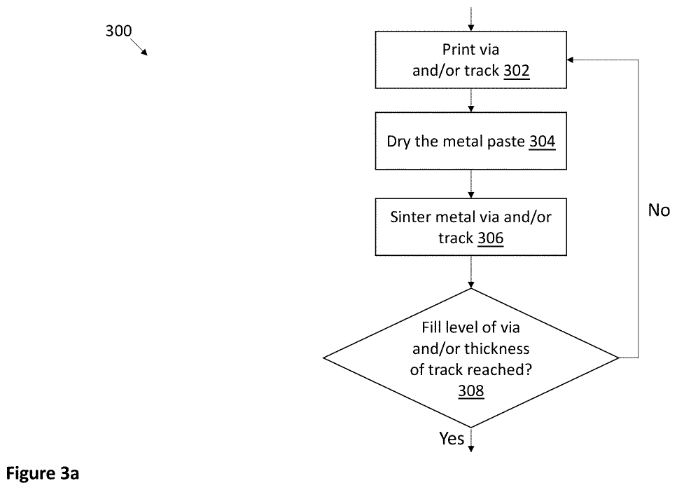

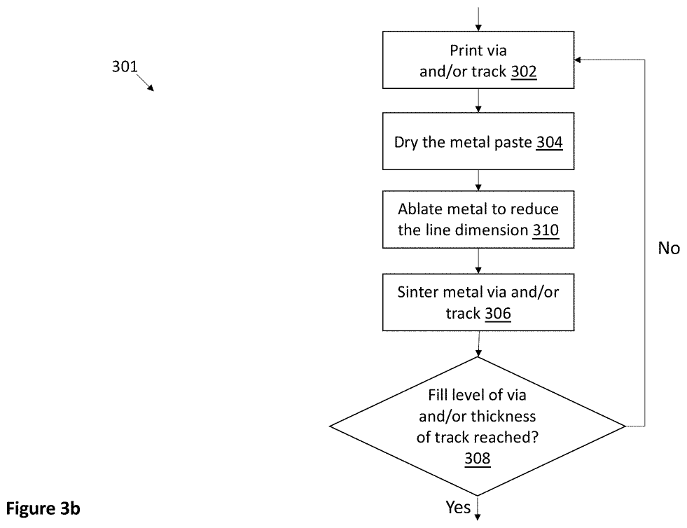

One embodiment of the metallization process is illustrated schematically in the flow diagram 300 depicted in FIG. 3a. First, a via or track is printed (i.e., in the case of a via, metal paste is deposited into a through hole, and in the case of a track or trace, metal paste is deposited on the PCB substrate or other layer) by laser jetting of a metal paste (e.g., a Cu paste) (step 302). The metal paste is dried, releasing the solvent (step 304), and the metal is sintered (step 306). At step 308, the PCB is transported to an imaging unit to determine whether the desired fill level of a via or the desired track thickness was reached. If so (yes branch of step 308), the processing of the PCB continues to the next stage; otherwise (no branch of step 308), the PCB is returned for additional printing/deposition and the process repeats until the desired amount of metal has been printed (i.e., a desired thickness reached). As shown in flow diagram 301 depicted in FIG. 3b, an additional ablation step 310 may be performed to remove unwanted deposited metal before or after the sintering step 306.

At any layer of the PCB assembly, after the metallization has been carried out, a dielectric layer may be added to the board to reduce capacitance and avoid short circuits. There are several ways to add the dielectric layer, for example, by coating a liquid material and curing it or by hot pressing of a prepreg. Examples of such processes will now be explained.

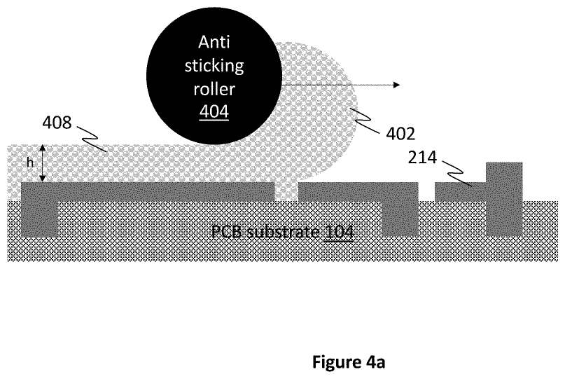

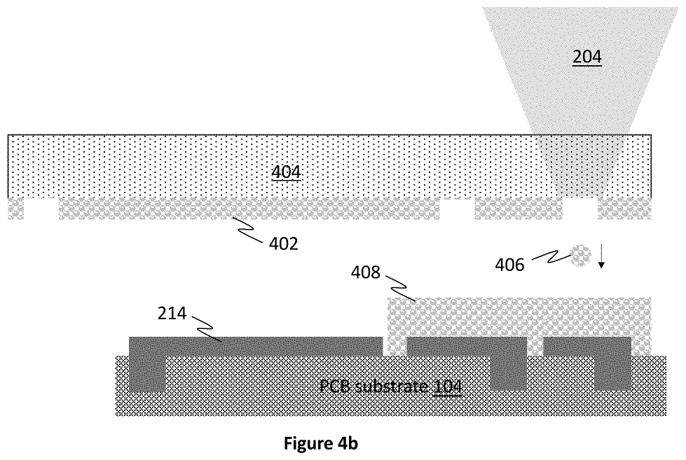

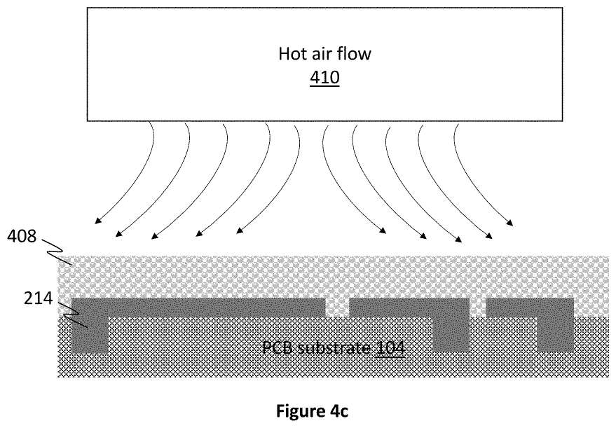

Referring to FIGS. 4a and 4b, a dielectric layer 408, which may be an epoxy and act as a passivation layer, may be deposited or coated over the metal layer 214 (or other layer) and/or the PCB substrate 104 with the aid of a roller or blade, see FIG. 4a, or by printing the dielectric layer 408 from a donor substrate 404 using the laser jetting system, as shown in FIG. 4b. In the case of coating a liquid epoxy 402 using a roller 404 or blade, the epoxy may be a viscous liquid that includes a filler, such as silica balls. An amount of epoxy 402 is applied to one end of the board and the roller 404, which may be made of or coated with an anti-sticking material such as polytetrafluoroethylene, ceramic, silicone, or other material, is placed at a desired height over the metal layer 214 and moved transversely over the board to spread the epoxy 402 into a layer 408 in a uniform manner at a desired thickness “h”. In some cases, the roller 404 may be fixed in position, and the board moved underneath it to cause the epoxy to spread. Where a blade applicator is used instead of a roller 404, the blade angle with respect to the board will affect the vertical force applied on the epoxy. If the angle is too small, the epoxy 402 may not be squeezed into small apertures between portions of the metal layer 214. At the same time, if the blade pressure is too small, it may prevent the epoxy 402 from being cleanly applied to the board and if it is too high, it may result in epoxy leakage outside the desired coverage area. Accordingly, adjustment means for the blade angle should be provided and the blade angle adjusted according to the epoxy viscosity and other characteristics.

Alternatively, as shown in FIG. 4b, the epoxy 402 may be applied in a thin layer to a substrate or foil 404, and then deposited in small amounts 406 (e.g., droplets) onto the metal layer 214 and/or PCB substrate 104 by laser jetting using the same laser that produced beam 204 that was also used for jetting the metal layer. The epoxy 402 may be applied to the substrate 404, which is transparent or nearly so at the wavelengths of laser beam 204, by a roller system (not depicted) in which the substrate is passed between a pair of rollers or a single roller and a fixed surface separated by a well-defined gap so as to ensure the resulting coating of epoxy 402 is of uniform thickness. For example, such a coating system (not depicted) may include a syringe of the epoxy and an air or mechanical pump that drives the epoxy onto the donor substrate 404. The donor substrate 404 may then be moved towards the well-defined gap to create the uniform layer of epoxy 402 with a thickness that is defined by the gap. In some embodiments of the invention, the donor substrate 404 can translated bidirectionally in a controlled manner, while opening the gap between the coater rollers, creating the possibility for recoating the same area of the donor substrate 404 with the epoxy without contamination to the rollers and reducing or eliminating the amount of donor substrate 404 consumed during the coating process, thereby preventing waste.

Once coated, the donor substrate 404 with the layer of epoxy 402 thereon is positioned in the laser jetting system and dots 406 of the epoxy 402 are jetted onto the metal layer 214 and/or PCB substrate 104 using the laser beam 204. In one example, the laser beam 204 is focused onto the interface between the layer of epoxy 402 and the substrate 404 causing local heating followed by a phase change and high local pressure which drives jetting of the epoxy onto the metal layer 214 and/or PCB substrate 104. After printing the epoxy 402 to the metal layer 214 and/or PCB substrate 104, the donor substrate 404 can be returned for a second (or additional) coating of epoxy 402 by reversing the direction of a transport mechanism or, where the donor substrate 404 is a continuous film, by moving the donor substrate 404 through the coating system in a loop-like process.

In still further embodiments, the donor substrate 404 may be a screen or grid in which the epoxy 402 is introduced into holes of the screen by a coater, which may be a roller or blade, and the incident laser beam 204 used to displace the epoxy 402 from the holes in the screen onto the metal layer 214 and/or PCB substrate 104.

Referring to FIG. 4c, after printing or coating the epoxy layer 408, heat is applied to the layer by hot air 410, IR irradiation, and/or other heating method(s) and the epoxy layer 408 is cured.

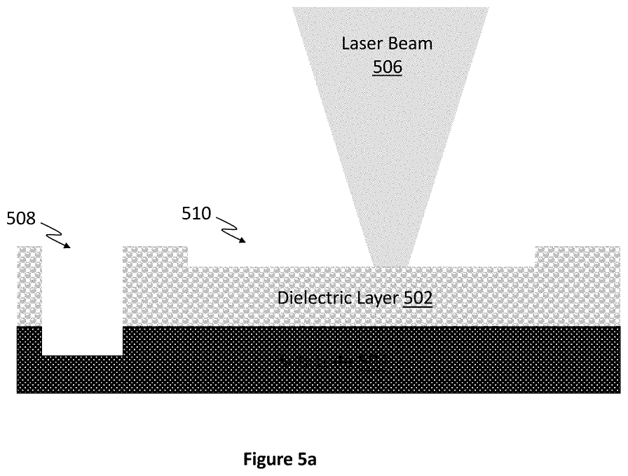

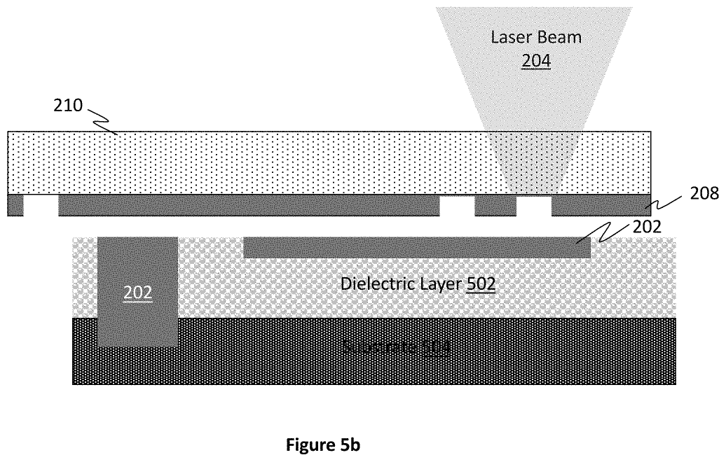

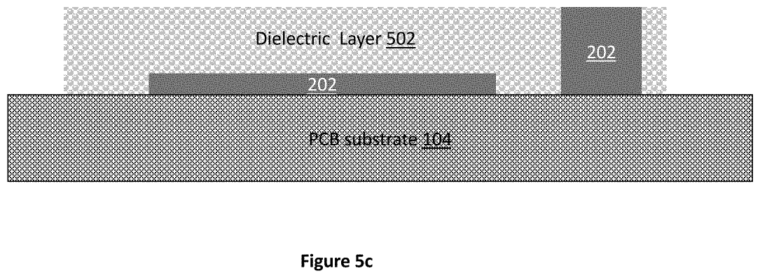

Yet another approach for passivation is to use a dielectric material to create a passivation layer. The use of dielectric material reduces height differences in a surface and creates a much more uniform height PCB surface. A dielectric material passivation layer can be formed by printing the metal (e.g., Cu) onto the dielectric material and attaching the resulting structure to the surface (FIGS. 5a-5c).

In this process, a dielectric layer 502 is formed on a substrate 504 (this substrate distinct from the PCB substrate) and a laser beam 506 is used to engrave/cut the dielectric layer 502 into a desired configuration, e.g., by creating through holes 508 and/or channels 510 in the dielectric material 502 (FIG. 5a). The engraved areas are filled with metal (e.g., Cu) 202 using the laser beam 204 to deposit the metal from a film 208 coated on a donor substrate 210 (FIG. 5b), and only then is the dielectric material 502 with the metal fillings 202 attached (e.g., by hot pressing) to the PCB substrate 104 (or a previously formed dielectric material layer) to create the layer of both metal and passivation (FIG. 5c). For the sake of clarity, it is noted that the dielectric material 502 with the metal fillings 202 has been flipped upside down from FIG. 5b to FIG. 5c. This approach for passivation can enhance the efficiency of the PCB build cycle significantly since the build of the layer and the attachment of the layer can be performed as two independent stages, allowing serialization thereof.

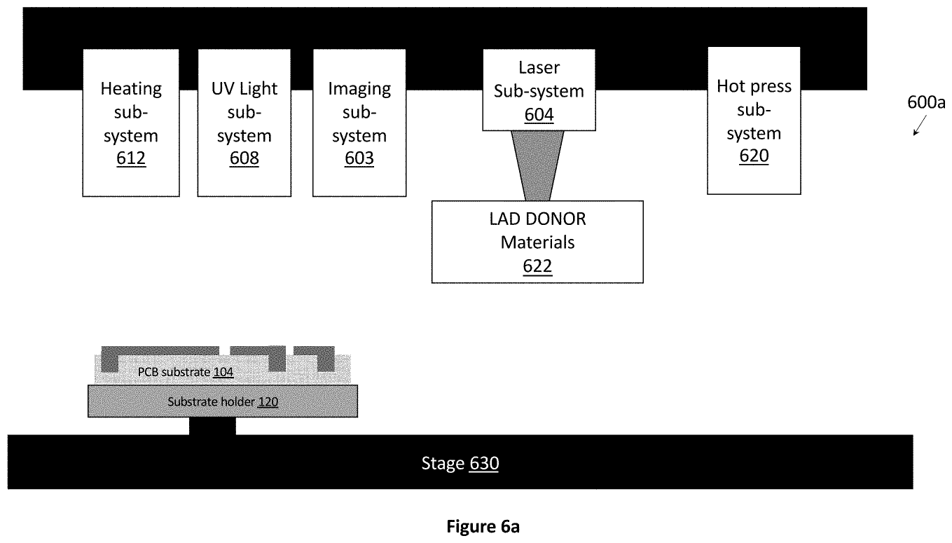

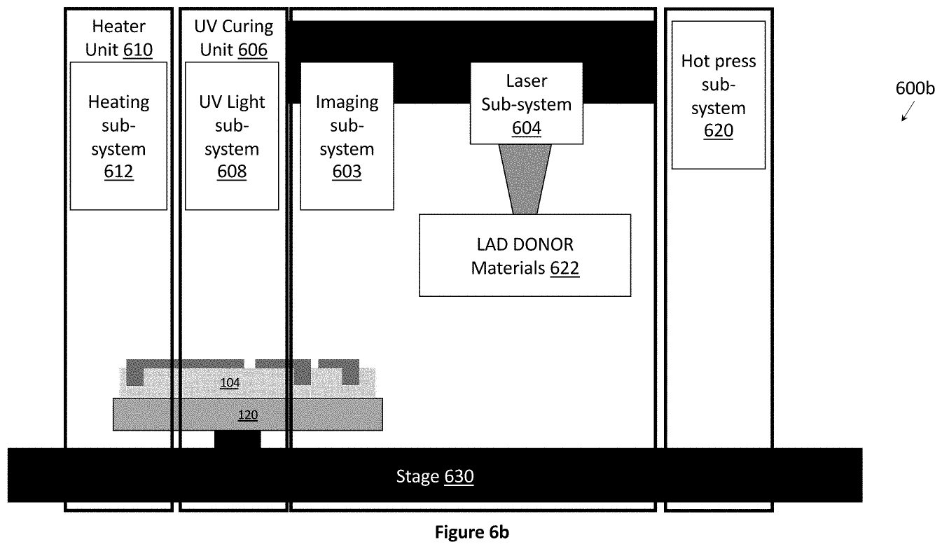

In FIGS. 6a and 6b, examples of PCB processing systems 600a and 600b configured in accordance with embodiments of the present invention are illustrated. FIG. 6a illustrates a system 600a, composed of individual sub-units, while FIG. 6b illustrates a system 600b, in which the sub-systems are arranged into various modules. In these example, PCB processing systems 600a and 600b include an imaging sub-system 603 and a laser sub-system 604, which together may be organized into a printing unit 602. A UV light sub-system 608 may be included in a UV curing unit 606, although this is an optional component. A heating sub-system 612 may be a component of a heating unit 610. A hot press sub-system 620 is available for final pressing and curing. Additionally provided with the printing unit 602 are various materials 622 for the LAD procedures discussed above. These include the metal used for conductive traces (e.g., Cu), dielectric material, etc. as well as the donor substrate(s) on which these materials are coated for deposition onto the PCB substrate 104. Although not shown in the diagrams, while the printing unit 602 can include only a laser sub-system 604 that is for all the laser deposition processes, it may also include an inkjet head or screen printer for printing the dielectric material.

Although not discussed in detail above, imaging sub-system 603 may be employed in connection with any or all of the above-described etching and deposition procedures. For example, the imaging sub-system 603 may include one or more two-dimensional and/or three-dimensional imaging units (e.g., cameras, scanning laser arrangements, etc.) that image the PCB assembly, PCB substrate 104 or portions thereof at various stages during the production process. Vias, through holes and/or features of the PCB assembly may be imaged so as to ensure they are free from debris and regular in shape. Deposited layers may be imaged so as to ensure they are uniform in coverage and/or accurately positioned. This may be especially important where layers are printed through successive jetting of small droplets of material. The imaging may also be used to ensure accurate registration of the PCB substrate 104 on a holder 120. Imaging in this fashion can allow for in-line repair of a process step, such as additional or re-coating of a layer, or rejection of an in-process PCB when necessary. Stage 630, which can translate in two dimensions (and where necessary, raise and lower the PCB 104), facilitates movement of the PCB between the various units of systems 600b and the sub-systems within those units during processing.

As mentioned above, the UV light sub-system 608, whether modularized or not, is optional. As all of the deposited layers can be heat-cured, the use of UV curing is not mandatory, hence, the need for the UV light sub-system 608 is only in cases where UV curing is preferred. When modularized, the UV light sub-system 608 can be included in the overall system 600a, 600b or removed therefrom as desired.

The heating sub-system 612 is used for curing heat sensitive materials and/or for drying solvent base materials. It can be a part of an overall system 600a, but it preferably is modularized (as part of heater unit 610) so that it can be easily replaced, if necessary, in a system 600b.

An additional hot press sub-system 620 is used for fusing the different layers together to form the PCB substrate 104.

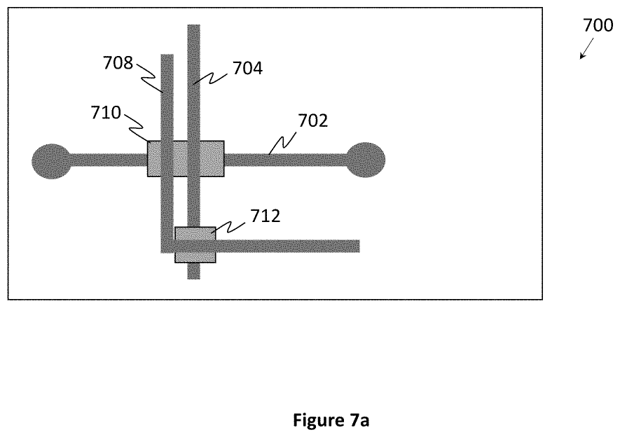

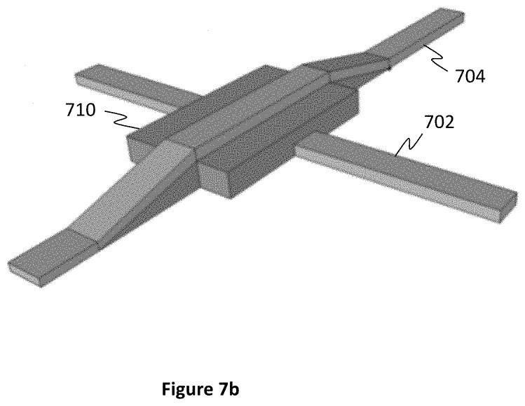

FIG. 7a illustrates an example of a PCB 700 that includes crossed metal (e.g., Cu) lines 702, 704, 706. Using conventional PCB production processes, fashioning PCB 700, if even possible, would entail several productions stages, consuming significant production time. It may even require the use of a double-sided PCB. In a PCB production system employing the methods of the present invention, however, production complexity and time are significantly reduced. For example, using one or more of the above-described techniques, dielectric patches 710, 712 may be printed using laser jetting, allowing the printing of metal lines 702, 704, 706 on a single side of PCB 700 and, optionally, using the same laser jetting apparatus as is used to print the dielectric patches. FIG. 7b provides a close-up three-dimensional view of one of the wire crossings on PCB 700 illustrated in FIG. 7a. After printing metal line 702, the dielectric patch 710 can be printed so that subsequent metal line 704 passes over line 702 on the same side of PCB 700, without creating a short circuit. This simple example illustrates how complex double-sided boards of the past can be fashioned in a relatively straightforward manner using the laser jetting techniques for different materials as discussed above. Of course, the present systems and methods may also be used to fashion double-sided PCBs, with or without bridging structures such as dielectric patch 710, thereby facilitating the production of single and double-sided boards, with bridged and non-bridged areas.

Although not illustrated in detail, it should be appreciated that the various components of the printing systems described herein operate under the control of one or more controllers, which, preferably, are processor-based controllers that operate under the instruction of machine-executable instructions stored on tangible machine-readable media. Such controllers may include a microprocessor and memory communicatively coupled to one another by a bus or other communication mechanism for communicating information. The memory may include a program store memory, such as a read only memory (ROM) or other static storage device, as well as a dynamic memory, such as a random-access memory (RAM) or other dynamic storage device, and each may be coupled to the bus for providing and storing information and instructions to be executed by the microprocessor. The dynamic memory also may be used for storing temporary variables or other intermediate information during execution of instructions by the microprocessor. Alternatively, or in addition, a storage device, such as a solid state memory, magnetic disk, or optical disk may be provided and coupled to the bus for storing information and instructions. The controller may also include a display, for displaying information to a user, as well as various input devices, including an alphanumeric keyboard and a cursor control device such as a mouse and/or trackpad, as part of a user interface for the printing system. Further, one or more communication interfaces may be included to provide two-way data communication to and from the printing system. For example, network interfaces that include wired and/or wireless modems may be used to provide such communications.

1. A method of fabricating of a printed circuit board (PCB) assembly, comprising:
depositing a first dielectric layer on a first region of a PCB substrate by a laser-assisted deposition (LAD) process;
depositing a first metal layer on a second region of the PCB substrate by a second LAD process in which jetting of metal droplets from a first donor substrate onto the second region of the PCB substrate and/or into one or more through holes in the second region of the PCB substrate is effected using a laser to form the first metal layer on the second region of the PCB substrate, the first metal layer being subsequently dried and sintered, with the jetting, drying, and sintering being repeated until the first metal layer reaches a desired thickness; and
forming at least one passivation layer over the first metal layer.

2. The method of claim 1, further comprising ablating the first metal layer.

3. The method of claim 2, wherein the ablating is performed using the laser that is used to jet the metal droplets from the donor substrate.

4. The method of claim 1, wherein the passivation layer comprises a second dielectric layer deposited or coated over the first metal layer using a roller or blade.

5. The method of claim 1, wherein the passivation layer comprises a second dielectric layer printed over the first metal layer from a dielectric coat on a second donor substrate by a third LAD process.

6. The method of claim 5, further comprising printing a second metal layer over the second dielectric layer by a fourth LAD process.

7. The method of claim 6, wherein the first metal layer includes a first metal trace, the first dielectric layer includes at least a first portion of dielectric that covers at least a first portion of the first metal trace, and the second metal layer includes a second metal trace having at least a portion disposed over the first portion of the first dielectric layer that covers the first portion of the first metal trace.

8. The method of claim 5, further comprising curing the first dielectric layer by hot air and/or infrared (IR) irradiation.

9. The method of claim 1, further comprising compressing, using a hot press, at least the first metal layer after the first metal layer has reach the desired thickness.
